(19) United States
(12) Patent Application Publication
(10) Pub. No.: US 2004/0000668 A1
(43) Pub. Date: Jan. 1, 2004

(54) [THIN-FILM TRANSISTOR ARRAY SUBSTRATE]

(76) Inventor: Jian-Shen Yu, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/250,033

(22) Filed: May 30, 2003

(30) Foreign Application Priority Data
Jun. 26, 2002 (TW) 91113976

(51) Int. Cl. G02F 1/136; H01L 29/04

(52) U.S. Cl. 257/72; 257/59; 438/149; 438/151

(57) ABSTRACT

A thin-film transistor array substrate, having a plurality of scan lines, a plurality of data lines and a plurality of pixels. Each pixel is located between two neighboring scan lines and two neighboring data lines. Each pixel has a thin-film transistor and a corresponding pixel electrode. A conductive line is formed under each pixel electrode, while a storage capacitor is formed of the conductive line and each of the pixel electrodes over the conductive line. The conductive line is parallel to one of the scan lines and extends from the thin-film transistor array to the edge of the thin-film transistor array substrate, which is connected to the corresponding scan line. Therefore, the RC delay of the scan line can be improved.

### CROSS REFERENCE TO RELATED APPLICATIONS

This application claims the priority benefit of Taiwan application serial no. 91113976, filed Jun. 26, 2002.

### BACKGROUND OF INVENTION

1. Field of the Invention

The invention relates in general to a thin-film transistor (TFT) array substrate, and more particularly, to a storage capacitor on the thin-film transistor array substrate.

2. Related Art of the Invention

A thin-film transistor liquid crystal display (LCD) consists of a thin-film transistor device and a liquid crystal display device. The thin-film transistor device includes a plurality of thin-film transistors arranged as an array. Each of the thin-film transistors has a pixel electrode, and each thin-film transistor comprises a gate, a channel layer, and a source/drain region stacked on a substrate. The thin-film transistors are used as the switching devices for the liquid crystal display device.

The operation theory of the thin-film transistor device is similar to that of the semiconductor MOS device. The thin-film transistor is a tri-polar device having a gate, a source region and a drain region. Normally, the thin-film transistor is made of amorphous silicon and polysilicon, while the technique of the amorphous silicon thin-film transistor is more mature than any other. While fabricating the thin-film transistor and the pixel electrode thereof, the pixel storage capacitor is simultaneously formed for charge storage.

FIG. 1 shows a top view of a conventional pixel storage capacitor.

A plurality of scan lines, a plurality of data lines and a plurality of pixels are formed on a thin-film transistor array substrate. Each pixel is located between two neighboring scan lines and two neighboring data lines.

Referring to FIG. 1, the pixel 100 is controlled by one data line 104 and one scan line 102b. The pixel 100 has a thin-film transistor 106a and a pixel electrode 108. The pixel electrode 108 is located corresponding to the thin-film transistor 106a. A source region 105a of the thin-film transistor 106a is electrically connected to the data line 104, a gate of the thin-film transistor 106a is electrically connected to the scan line 102b, and a drain region 107a thereof is electrically connected to the pixel electrode 108.

The conventional pixel 100 uses a scan line 102a and a pixel electrode 108 covering the scan line 102a to form a storage capacitor. In other words, a storage capacitor of the pixel 100 is formed of another scan line 102a neighboring to the scan line 102b controlling the pixel 100 and the pixel electrode 108 covering the scan line 102a. In addition, a capacitor dielectric layer (not shown) is formed between the scan line 102a and the pixel electrode 108. The capacitor dielectric layer is simultaneously formed while forming the gate insulation layer or the protection layer of the thin-film transistors 106a and 106b.

However, using the scan line 102a as the electrode of the storage capacitor directly increases the RC delay of the gate. Therefore, the operation speed is affected. Further, while mending the dark spot, the normal operational function of the scan line is affected.

### SUMMARY OF INVENTION

The present invention provides a thin-film transistor array substrate, on which a storage capacitor is formed with greatly reduced gate RC delay.

The present invention provides a thin-film transistor array substrate allowing dark spot repair without affecting the normal operation functions of the scan line.

The thin-film transistor array substrate comprises a plurality of scan lines, a plurality of data lines and a plurality of pixels. Each pixel is located between two neighboring scan lines and two neighboring data lines and comprises a thin-film transistor and a corresponding pixel electrode. The thin-film transistor is electrically connected to one of the scan lines. A conductive line is formed under the pixel electrode. The conductive line and each pixel electrode form a storage capacitor. The conductive line is parallel to the scan lines and extends from the thin-film transistor array to the edge of the thin-film transistor array substrate, such that the edge of the thin-film transistor array substrate is electrically connected to the scan line electrically connected to the thin-film transistor of the neighboring pixel.

In the present invention, a conductive line is formed under the pixel electrodes to form the storage capacitor. Therefore, the increased gate RC delay for the conventional storage capacitor that uses the scan line as the electrode is avoided.

In the present invention, the storage capacitor is formed of the conductive line and the pixel electrode, so that the normal operational functions of the scan line can be maintained while repairing dark spots.

### BRIEF DESCRIPTION OF DRAWINGS

These, as well as other features of the present invention, will become more apparent upon reference to the drawings.

FIG. 1 shows a top view of a conventional pixel.

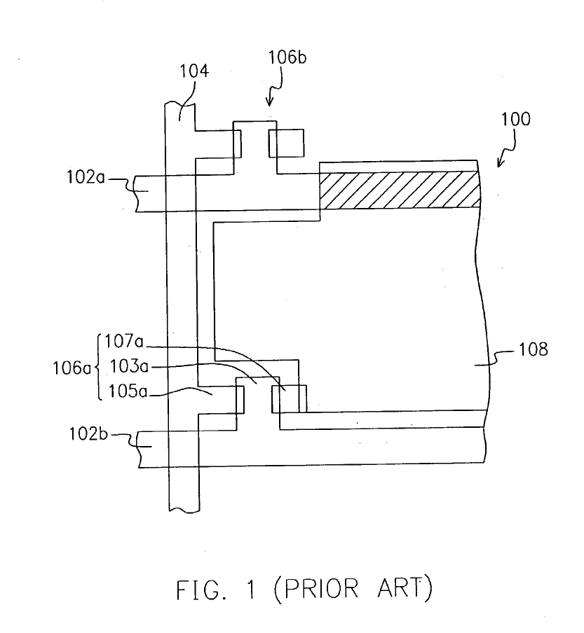

FIG. 2 shows a top view of a thin-film transistor array substrate in one embodiment of the present invention.

FIG. 3 shows a top view of a pixel as shown in FIG. 2.

### DETAILED DESCRIPTION

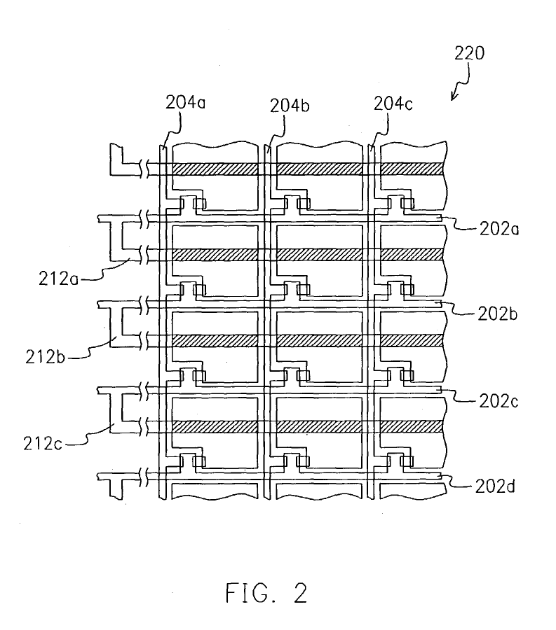

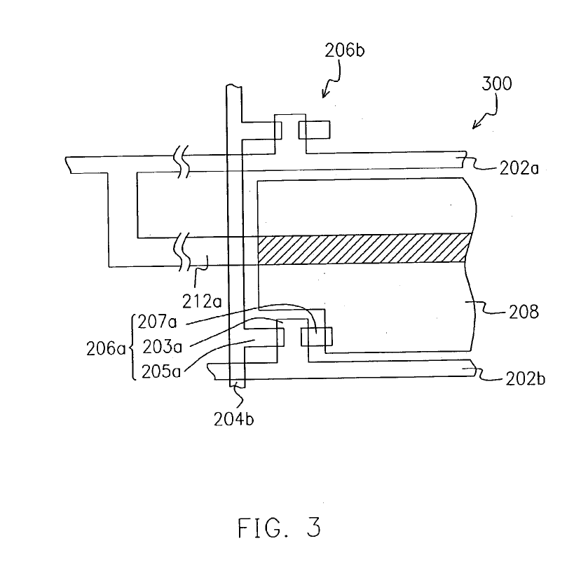

In FIG. 2, a top view of a thin-film transistor array substrate in one embodiment of the present invention is shown; while FIG. 3 shows the top view of the pixel as shown in FIG. 2.

Referring to FIG. 2, a thin-film transistor array substrate 220 comprises a plurality of data lines 204a, 204b, 204c, a plurality of scan lines 202a, 202b, 202c, 202d, and a plurality of pixels. Each pixel is located between two neighboring scan lines and two neighboring data lines. In this embodiment, the scan direction is from the top to the bottom, for example, from the scan line 202a, 202b to 202c. In addition, the scan direction of the thin-film transistor array substrate 220 is also from the bottom to the top such as from the scan line 202d, 202c, 202b, to 202a.

Each pixel includes a pixel electrode and a corresponding thin-film transistor. A conductive line 212a, 212b or 212c is formed under the pixel electrode of the pixels at the same row to form storage capacitors. One side of each of the conductive lines 212a, 212b, and 212c extends to the edge of the thin-film transistor array substrate 220, which is connected to the corresponding one of the scan lines 202a, 202b and 202c.

Referring to FIG. 3, the pixel as shown in FIG. 2 is illustrated. The pixel 200 is controlled by a scan line 202b and a data line 204b. The pixel 200 includes a thin-film transistor 206a and a pixel electrode 208. The pixel electrode 208 is formed corresponding to the thin-film transistor 206a. The material for forming the pixel electrode 208 includes tin-oxide. The thin-film transistor 206a has a gate 203a, a source region 205a and a drain region 207a. The gate 203a is electrically connected to the scan line 202b, the source region 205a is electrically connected to the data line 204b, and the drain region 207a is electrically connected to the pixel electrode 208.

A conductive line 212a is formed under the pixel electrode 208 in parallel with the scan line 202b. The conductive line 212a can be formed simultaneously with the scan lines 202a and 202b. The material for forming the conductive line 212a includes metal. A storage capacitor is formed of the conductive line 212a and the pixel electrode 208. One side of the conductive line 212a extends to the edge of the thin-film transistor array substrate, such that the edge of the thin-film transistor array substrate is connected to a scan line 202a neighboring the scan line 202b.

A capacitor dielectric layer (not shown) is further formed between the conductive line 212a and the pixel electrode 208. The capacitor dielectric layer can be formed as a part of a gate insulation layer or a protection layer of the thin-film transistors 206a and 206b. The material for forming the capacitor dielectric layer includes silicon nitride, silicon oxide, Ta₂O₅, TaO₂, or titanium oxide.

In the thin-film transistor array substrate of the present invention, a conductive line 212a is formed under the pixel electrode 208 to form a storage capacitor. Therefore, increase of RC delay of the gate by directly using the scan line 202a as the electrode of the capacitor is avoided. In addition, as the storage capacitor is not formed on the scan line 202a, the dark spot repair will not affect the normal operation of the scan line 202a. Further, the storage capacity of the thin-film transistor array substrate is not lower than that of the conventional storage capacitor.

Accordingly, the present invention has the following advantages: 1. A conductive line is formed under the pixel electrode, such that the storage capacitor is formed of the conductive line and the pixel electrode to avoid increasing the RC delay of the gate by directly using the scan line as the capacitor electrode. 2. A conductive line is formed under the pixel electrode, such that the storage capacitor is formed of the conductive line and the pixel electrode to avoid affecting normal operation of the scan line by directly using the scan line as the capacitor electrode.

Other embodiments of the invention will appear to those skilled in the art from consideration of the specification and practice of the invention disclosed herein. It is intended that the specification and examples be considered as exemplary only, with a true scope and spirit of the invention being indicated by the following claims.

1. A thin-film transistor array substrate, comprising a plurality of scan lines, a plurality of data lines, and a plurality of pixels, wherein each pixel is formed between two neighboring data lines and two neighboring scan lines, each pixel further comprising:
a thin-film transistor, electrically connected to the corresponding scan line;
a pixel electrode, located corresponding to the thin-film transistor; and
a conductive line, formed under the pixel electrode and parallel to the scan corresponding line, the conductive line extending to a peripheral region of the thin-film transistor array substrate, electrically connected to the corresponding scan line.

2. The thin-film transistor array substrate according to claim 1, wherein the pixel electrode includes tin oxide.

3. The thin-film transistor array substrate according to claim 1, wherein the conductive line is formed simultaneously with the scan line.

4. The thin-film transistor array substrate according to claim 3, wherein the conductive line consists of aluminum and molybdenum.

5. The film transistor array substrate according to claim 1, further comprising a capacitor dielectric layer formed between the conductive line and the pixel electrode.

6. The film transistor array substrate according to claim 5, wherein the capacitor dielectric layer is formed of a material selected from a group consisting of silicon nitride, silicon oxide, Ta₂O₅, TaO₂ and titanium oxide.
